(19) United States
(12) Patent Application Publication
(10) Pub. No.: US 2023/0002906 A1
(43) Pub. Date: Jan. 5, 2023

(54) CONTINUOUS-FEED CHEMICAL VAPOR DEPOSITION SYSTEM

(71) Applicants: MELLANOX TECHNOLOGIES, LTD., Yokneam (IL); BAR-ILAN UNIVERSITY, Ramat Gan (IL); RAMOT AT TEL- AVIV UNIVERSITY LTD., Tel Aviv (IL); SIMTAL NANO-COATINGS LTD, Shimshit (IL)

(72) Inventors: Elad MENTOVICH, Tel Aviv (IL); Yaniv ROTEM, Nesher (IL); Yaakov GRIDISH, Yoqneam Ilit (IL); Doron NAVEH, Petah-Tikva (IL); Chen STERN, Kiryat Ono (IL); Yosi BEN-NAIM, Eilat (IL); Ariel ISMACH, Rosh Haain (IL); Eran BAR-RABI, Shimshit (IL); Tal KAUFMAN, Shimshit (IL)

(21) Appl. No.: 17/305,203

(22) Filed: Jul. 1, 2021

(51) Int. Cl. C23C 16/54; C23C 16/46; C23C 16/52

(52) U.S. Cl. CPC C23C 16/54; C23C 16/46; C23C 16/52

(57) ABSTRACT

A continuous-feed chemical vapor deposition system and an associated method are provided. An example of the continuous-feed chemical vapor deposition system includes a first chamber configured to receive a substrate. The continuous-feed chemical vapor deposition system includes a second chamber downstream from the first chamber and configured to receive the substrate from the first chamber. The second chamber is configured to perform a chemical vapor deposition process on the substrate. The continuous-feed chemical vapor deposition system includes a third chamber downstream from the second chamber that is configured to receive the substrate from the second chamber upon completion of the chemical vapor deposition process. The second chamber can be environmentally isolated from the first chamber and the third chamber. The first chamber is further configured to receive a subsequent substrate when the chemical vapor deposition process is occurring in the second chamber.

### TECHNOLOGICAL FIELD

Example embodiments of the present disclosure relate generally to a continuous-feed chemical vapor deposition system and more particularly to a chemical vapor deposition system that allows for continuous and high-volume processing of substrates.

### BACKGROUND

Chemical vapor deposition is an industrial process used to deposit a thin film of a desired material on a substrate. Applicant has identified a number of deficiencies and problems associated with present systems and methods of chemical vapor deposition that limit both the quantity and the quality of desired material that can be produced. Through applied effort, ingenuity, and innovation, many of these identified problems have been solved by developing solutions that are included in embodiments of the present disclosure, many examples of which are described in detail herein.

### BRIEF SUMMARY

In an embodiment, a chemical vapor deposition system is provided. The chemical vapor deposition system comprises a first chamber configured to receive a substrate. The chemical vapor deposition system further comprises a second chamber downstream from the first chamber, where the second chamber is configured to receive the substrate from the first chamber, and where, in an operational state, a chemical vapor deposition process is performed on the substrate within the second chamber. The chemical vapor deposition system further comprises a third chamber downstream from the second chamber, where the third chamber is configured to receive the substrate from the second chamber upon completion of the chemical vapor deposition process within the second chamber, and where the second chamber is configured to be environmentally isolated from the first chamber and the third chamber when in the operational state, and where, in the operational state, the first chamber is configured to receive a subsequent substrate in preparation for a subsequent chemical vapor deposition process to be performed on the subsequent substrate.

In some embodiments, in the operational state, the third chamber is configured to allow a user to withdraw a previous substrate, where the previous substrate has previously undergone the chemical vapor deposition process within the second chamber. Further, in some embodiments, the first chamber is configured to be at a first pressure when receiving the subsequent substrate and where the third chamber is configured to be at the first pressure when allowing the user to withdraw the previous substrate.

In some embodiments, the second chamber is at a second pressure.

In some embodiments, the chemical vapor deposition system further comprises a first mechanism configured to be actuated to transfer the substrate from the first chamber to the second chamber and a second mechanism configured to be actuated to transfer the substrate from the second chamber to the third chamber.

In some embodiments, the substrate comprises a plurality of substrates. In some embodiments, the third chamber is actively cooled.

In another embodiment, a chemical vapor deposition method is provided. The chemical vapor deposition method includes providing a first chamber configured to receive a substrate. The chemical vapor deposition method further includes providing a second chamber downstream from the first chamber, where the second chamber is configured to receive the substrate from the first chamber, and where, in an operational state, a chemical vapor deposition process is performed on the substrate within the second chamber. The chemical vapor deposition method further includes providing a third chamber downstream from the second chamber, where the third chamber is configured to receive the substrate from the second chamber upon completion of the chemical vapor deposition process within the second chamber, where the second chamber is configured to be environmentally isolated from the first chamber and the third chamber when in the operational state, and where, in the operational state, the first chamber is configured to receive a subsequent substrate in preparation for a subsequent chemical vapor deposition process to be performed on the subsequent substrate.

In some embodiments, in the operational state, the third chamber is configured to allow a user to withdraw a previous substrate, where the previous substrate has previously undergone the chemical vapor deposition process within the second chamber. Further, in some embodiments, the first chamber is configured to be at a first pressure when receiving the subsequent substrate and where the third chamber is configured to be at the first pressure when allowing the user to withdraw the previous substrate.

In some embodiments, the second chamber is at a second pressure.

In some embodiments, the chemical vapor deposition method further includes providing a first mechanism configured to be actuated to transfer the substrate from the first chamber to the second chamber and providing a second mechanism configured to be actuated to transfer the substrate from the second chamber to the third chamber.

In some embodiments, the substrate comprises a plurality of substrates.

In some embodiments, the third chamber is actively cooled.

In yet another embodiment, a chamber for conducting chemical vapor deposition is provided. The chamber comprises a heating enclosure configured to maintain a substrate at a predefined temperature for conducting a chemical vapor deposition process within the chamber, where the heating enclosure comprises a cylindrical body having a first end and a second end. The chamber further comprises a first valve proximate the first end of the cylindrical body, where the substrate is received within the cylindrical body via the first valve and where the first valve is configured to environmentally isolate the chamber when in an operational state during which the chemical vapor deposition process is performed on the substrate. The chamber further comprises a second valve proximate the second end of the cylindrical body, where the substrate is discharged from the chamber via the second valve and where the second valve is configured to environmentally isolate the chamber when in the operational state. The chamber further comprises a first tubular connector and a second tubular connector, the first tubular connector engaged with the first valve and the first opening of the cylindrical body and extending between the first valve and the first opening, the second tubular connector engaged with the second opening of the cylindrical body and the second valve and extending between the second opening and the second valve, where the first tubular connector and the second tubular connector mechanically isolate the cylindrical body from the first valve and the second valve.

In some embodiments, the first tubular connector comprises first flexible bellows and the second tubular connector comprises second flexible bellows.

In some embodiments, the first valve comprises a first gate valve and the second valve comprises a second gate valve.

In some embodiments, a surface of the first valve is mirror polished and a surface of the second valve is mirror polished.

In some embodiments, the second valve is actively cooled.

In yet another embodiment, a heating enclosure for conducting chemical vapor deposition is provided. The heating enclosure comprises a cylindrical body having a first end and a second end, where the cylindrical body is configured to receive a substrate. The heating enclosure further comprises a first plurality of heating elements disposed around an outer surface of the cylindrical body and extending along an axial direction of the cylindrical body from the first end of the cylindrical body toward the second end of the cylindrical body, where a first length of the each of the first plurality of heating elements is less than half a length of the cylindrical body. The heating enclosure further comprises a second plurality of heating elements disposed around the outer surface of the cylindrical body and extending along an axial direction of the cylindrical body from the first end of the cylindrical body to the second end of the cylindrical body. The heating enclosure further comprises a third plurality of heating elements disposed around the outer surface of the cylindrical body and extending along an axial direction of the cylindrical body from the second end of the cylindrical body toward the first end of the cylindrical body, where a second length of each of the third plurality of heating elements is less than half the length of the cylindrical body, and where the first plurality of heating elements, the second plurality of heating elements, and the third plurality of heating elements are configured to maintain a first temperature within the cylindrical body.

In some embodiments, the heating enclosure further comprises a controller and a plurality of temperature sensors configured to measure temperatures in the cylindrical body, where the plurality of temperature sensors are in communication with the controller, and where the controller is further configured to control at least one of the first, second, and third plurality of heating elements at least partly in response to measurements of the plurality of temperature sensors.

In some embodiments, the first plurality of heating elements and the third plurality of heating elements are set at a second temperature and the second plurality of heating elements are set at a third temperature. In some embodiments, the second temperature is greater than the third temperature.

In some embodiments, the cylindrical body comprises quartz.

In some embodiments, the first plurality of heating elements, the second plurality of heating elements, and the third plurality of heating elements comprise silicon carbide.

In some embodiments, the heating enclosure further comprises an insulator around the outer surface of the cylindrical body. In some embodiments, the insulator comprises ceramic.

In yet another embodiment, a chemical vapor deposition system is provided. The chemical vapor deposition system comprises a first chamber configured to receive a substrate, where, in an operational state, a chemical vapor deposition process is performed on the substrate within the second chamber, where the second chamber is configured to be environmentally isolated from the first chamber when in the operational state, and where the first chamber is configured to receive the substrate from the second chamber upon completion of the chemical vapor deposition process within the second chamber.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Having described certain example embodiments of the present disclosure in general terms above, reference will now be made to the accompanying drawings. The components illustrated in the figures may or may not be present in certain embodiments described herein. Some embodiments may include fewer (or more) components than those shown in the figures.

FIG. 1 illustrates an example continuous-feed chemical vapor deposition (CVD) system in accordance with one or more embodiments of the present invention;

FIG. 2 is a perspective sectional view of the continuous-feed CVD system of FIG. 1 in accordance with one or more embodiments of the present invention;

FIG. 3 is a perspective view of an example heating enclosure in accordance with one or more embodiments of the present invention;

FIG. 4 is a schematic illustration of the heating enclosure described in FIG. 3 in accordance with one or more embodiments of the present invention; and

FIG. 5 is a flowchart illustrating an example method of using a continuous-feed CVD system in accordance with one or more embodiments of the present invention.

### DETAILED DESCRIPTION

### Overview

Embodiments of the present disclosure now will be described more fully hereinafter with reference to the accompanying drawings in which some but not all embodiments are shown. Indeed, the present disclosure may be embodied in many different forms and should not be construed as limited to the embodiments set forth herein; rather, these embodiments are provided so that this disclosure will satisfy applicable legal requirements. Like numbers refer to like elements throughout. As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

Chemical vapor deposition (CVD) is an industrial process that uses chemical reactions to deposit a thin film of a desired material onto a substrate for use in a variety of technical applications. In many conventional CVD systems, a substrate may be placed inside a reactive chamber of the CVD system. Once the substrate is inside the reactive chamber, the pressure in the reactive chamber may be adjusted to ensure that the pressure is at substantially vacuum pressure, and the temperature in the reactive chamber is increased to a necessary reactive temperature. Then, deposition gases are introduced into the reactive chamber causing a reaction to occur that deposits a thin film of the desired material onto the substrate. After enough of the desired material has been deposited onto the substrate, the deposition gases are removed from the reactive chamber, the temperature is reduced to a safe handling temperature, and the pressure in the reactive chamber may be adjusted to allow for the substrate to be discharged, or removed, from the reactive chamber.

Producing the desired material using the conventional CVD system described above limits the amount of the desired material that can be produced within a time frame because the conventional CVD system suffers from long periods of pressure and temperature adjustment in which a CVD process is not being performed on the substrate. In particular, each time a new substrate is placed inside the reactive chamber, there is a waiting period while the reactive chamber is brought to substantially vacuum pressure and the necessary reactive temperature. Then, after the deposition of the desired material on the substrate is complete, there is another waiting period while the deposition gases are evacuated from the reactive chamber, the temperature is reduced to the safe handling temperature, and the pressure is increased to substantially atmospheric pressure.

Further, conventional CVD systems and methods as described above are unable to produce high-quality large sheets of the desired material. In order to produce high-quality material using CVD, the region around the substrate in the reactive chamber must have a substantially uniform and a substantially stable temperature. However, reactive chambers of conventional CVD systems are only capable of providing the necessary temperature uniformity and stability over a small region. As such, conventional CVD systems are only able to produce either low-quality large sheets of the desired material or high-quality small sheets of the desired material.

Thus, to address the above identified issues of conventional CVD systems and methods, a continuous-feed CVD system for the mass production of high-quality large sheets of a desired material is disclosed herein. The system includes three independent chambers, each of which is capable of processing substrates simultaneously. In particular, the system includes an input chamber, a process chamber downstream from the input chamber and connected to the input chamber via a first gate valve, and an output chamber downstream from the process chamber and connected to the process chamber via a second gate valve. In some embodiments, the continuous-feed CVD system may include a substrate carrier and associated mechanisms for moving the substrate through the CVD system, such as the substrate carrier and associated mechanisms described in the application title CVD SYSTEM WITH SUBSTRATE CARRIER AND ASSOCIATED MECHANISMS FOR MOVING SUBSTRATE THERETHROUGH, Ser. No. ______, filed concurrently with the present application and the contents of which are hereby incorporated by reference in their entirety. Further, in some embodiments, the continuous-feed CVD system may include components configured for facilitating uniform and laminar flow, such as the components described in the application titled CVD SYSTEM WITH FLANGE ASSEMBLY FOR FACILITATING UNIFORM AND LAMINAR FLOW, Ser. No. ______, filed concurrently with the present application and the contents of which are hereby incorporated by reference in their entirety. Further, in some embodiments, the continuous-feed CVD system may be used to perform several types of processes, such as the processes described in the applications titled PROCESS FOR LAMINATING GRAPHENE-COATED PRINTED CIRCUIT BOARDS, Ser. No. ______; PROCESS FOR LAMINATING CONDUCTIVE-LUBRICANT COATED METALS FOR PRINTED CIRCUIT BOARDS, Ser. No. ______; PROCESS FOR LOCALIZED REPAIR OF GRAPHENE-COATED LAMINATION STACKS AND PRINTED CIRCUIT BOARDS, Ser. No. ______; PROCESS FOR APPLYING A TWO-DIMENSIONAL MATERIAL TO A TARGET SUBSTRATE POST-LAMINATION, Ser. No. ______; each of which is filed concurrently with the present application. The contents of each of the foregoing applications are hereby incorporated by reference in their entirety.

According to embodiments of the invention and as described in greater detail below, while the continuous-feed CVD system is in use, the process chamber is configured to continuously operate at substantially vacuum pressure and substantially at the necessary reactive temperature. The process chamber is further configured to, during an operational state, perform a chemical vapor deposition process on a substrate received from the input chamber. While the process chamber is in the operational state, the input chamber is configured to receive a subsequent substrate into the continuous-feed CVD system and, after receiving the subsequent substrate, reduce the pressure in the input chamber to substantially vacuum pressure in preparation for entry into the process chamber. Moreover, while the process chamber is in the operational state, the output chamber is configured to cool down a previous substrate that was received from the process chamber, increase the pressure in the output chamber to substantially atmospheric pressure, and discharge, or allow for the removal of, the previous substrate from the system. As a result, embodiments of the continuous-feed CVD system disclosed herein eliminate the long periods of pressure and temperature adjustment associated with many present systems and methods of CVD, thus enabling the mass production of the desired material in a cost-effective and timely manner.

Furthermore, embodiments of the invention and as described in greater detail below, enable the production of high-quality large sheets of the desired material. The process chamber, according to some embodiments, includes a unique heating enclosure that ensures temperature uniformity and stability throughout the heating enclosure. In particular, the heating enclosure comprises a cylindrical body that is surrounded by multiple heating elements. Some of the heating elements may extend the entire length of the cylindrical body (or even to a length greater than the entire length of the cylindrical body) while others may extend from the end of the cylindrical body to a distance that is shorter than the distance to the center of the cylindrical body. The heating elements can be independently controlled based on measurements taken by a plurality of temperature sensors, such that temperature uniformity and stability may be maintained throughout the heating enclosure.

While embodiments of the invention and as described in greater detail below may be applied to CVD processes for depositing a variety of materials, embodiments of the invention described herein may be advantageous in the production of large sheets of high-quality graphene. Graphene is a two-dimensional allotrope of carbon that comprises a single layer of carbon atoms arranged in a hexagonal honeycomb lattice. Graphene possess a unique combination of electromagnetic, thermal, and structural properties, such that graphene has the potential to revolutionize a variety of technologies, including electronic devices, optoelectronic devices, light emitting diodes, touch screens, electrical contacts, flexible electrodes, transparent electrodes, supercapacitors, batteries, Q-bit computing, optical sensors, chemical sensors, etc. However, successful implementation of graphene in such technologies has been severely limited by the inability of conventional CVD systems and methods to produce large sheets of high-quality graphene. Embodiments of the invention disclosed herein and described in greater detail below enable the production of large sheets of high-quality graphene.

### Continuous-Feed Chemical Vapor Deposition System

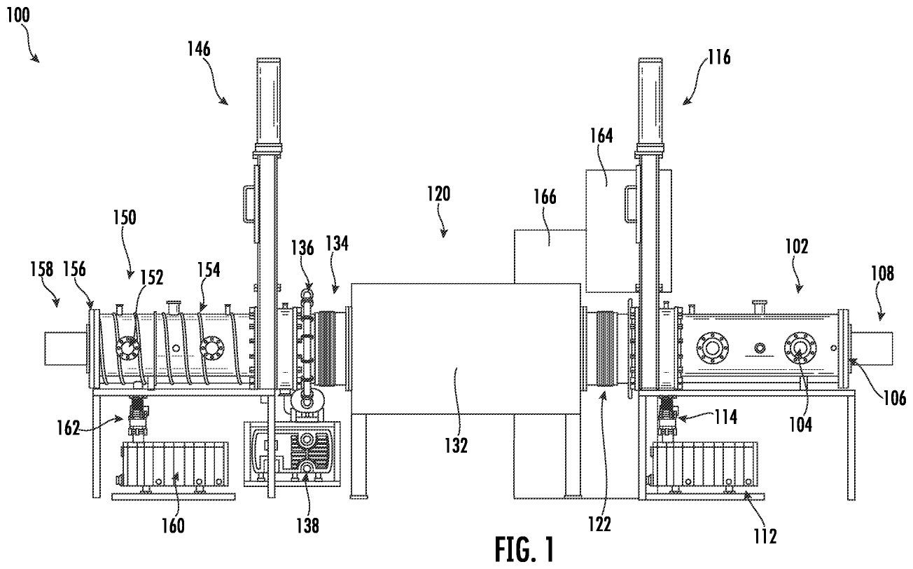

With reference to FIGS. 1-4, a continuous-feed CVD system 100 is illustrated. As shown, embodiments of the continuous-feed CVD system 100 may include an input chamber 102 configured for receiving a substrate. As described herein, the continuous-feed CVD system 100 may include a process chamber 120 downstream from the input chamber 102 and configured to receive the substrate from the input chamber 102. The process chamber 120 may be connected to the input chamber 102 via a first gate valve 116. The process chamber 120 may further be configured to perform a CVD process on the substrate when the process chamber is in an operational state.

The input chamber 102, in turn, may be configured to receive a subsequent substrate (e.g., a substrate that will be entering the process chamber 120 following the substrate currently being processed in the process chamber 120) while the CVD process is being performed on the substrate in the process chamber 120. Thus, the input chamber 102 may effectively be used to prepare a substrate for entry into the process chamber 120 while the process chamber 120 is in operation with respect to a different substrate.

In addition, the CVD system 100 may comprise an output chamber 150 downstream from the process chamber 120, and the output chamber 150 may be configured to discharge, or allow for the removal of, a previous substrate while the CVD process is being performed on the substrate in the process chamber 120. For example, the output chamber 150 may be configured to receive the substrate from the process chamber 120. The output chamber 150 may be connected to the process chamber 120 via a second gate valve 146. Thus, as described herein, the process chamber 120 may be configured to be environmentally isolated from the input chamber 102 and the output chamber 150 when the CVD process is being performed on the substrate within the process chamber 120.

As described herein, as an example, the substrate may comprise copper, nickel, cobalt, tungsten, silicon carbide, palladium, platinum, gold, or transition metal alloys. Said differently, the substrate may be any material upon which CVD can be performed. In some embodiments, each chamber may only contain one substrate at a time. In other embodiments, each chamber may contain a plurality of substrates (e.g., a batch of substrates) for processing at the same time. In some embodiments, the substrate may be inserted directly into the continuous-feed CVD system 100. In other embodiments, the substrate may be initially placed in a substrate carrier, and the substrate carrier may be inserted into the continuous-feed CVD system 100.

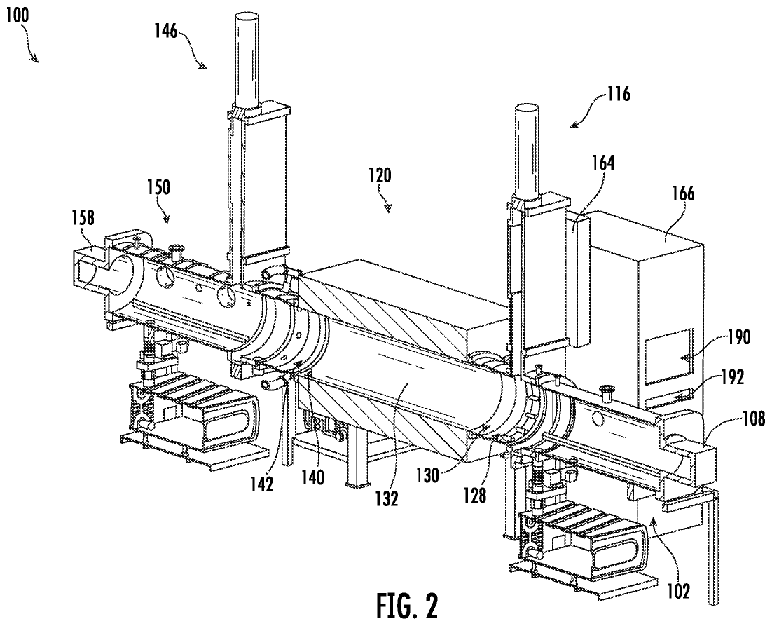

As described above, the continuous-feed CVD system 100 includes the input chamber 102 configured to receive the substrate. As shown in FIGS. 1 and 2, the input chamber 102 may be substantially cylindrical. In other embodiments, the input chamber 102 may be substantially rectangular. By way of example, the input chamber 102 may comprise stainless steel, aluminum, or quartz. Said differently, the input chamber 102 may comprise any material such that substantially vacuum pressure can be maintained inside the input chamber 102. The input chamber 102 may further include viewing windows 104 such that the interior of the input chamber 102 can be viewed by a user or an operator from outside the chamber.

As shown in FIG. 1, the substrate may be received via a first door 106 connected by a hinge or other mechanism to a first end of the input chamber 102. In some embodiments, the first door 106 may be configured to be manually opened. Alternatively, the first door 106 may be configured to automatically open when the continuous-feed CVD system 100 is ready to receive the substrate. In other embodiments, the input chamber 102 may be configured for receiving the substrate via an opening on a side of the input chamber 102.

In some embodiments, the input chamber 102 may comprise a first mechanism configured to transfer the substrate from the input chamber 102 to the process chamber 120. In some embodiments, the input chamber 102 may be configured such that the first mechanism may be stored in a first mechanism housing 108. The first mechanism may be configured to transfer the substrate from the input chamber 102 to the process chamber 120 when the input chamber 102 is at substantially vacuum pressure. In this way, in some embodiments, the first mechanism may be configured such that the substrate may be transferred from the input chamber 102 to the process chamber 120, either automatically or in response to actuation by a remote operator or a remote user.

In some embodiments, a pump 112 may be connected to the input chamber 102 for controlling the pressure in the input chamber 102. The pump 112 may be connected to the input chamber 102 via piping 114. In some embodiments, there may be one pump for the entire continuous-feed CVD system 100. In other words, in some embodiments, the same pump 112 may be used to control the pressure in the input chamber 102, the process chamber 120, and/or the output chamber 150.

In some cases, for example, the pump 112 may be configured to control the pressure in the input chamber 102 such that the input chamber 102 is at substantially atmospheric pressure when receiving the substrate and may further be configured to control the pressure in the input chamber 102 such that the input chamber 102 is at substantially vacuum pressure when the substrate is being transferred from the input chamber 102 to the process chamber 120. The pump 112 may also be configured to control the pressure in the input chamber 102 such that the pressure in the input chamber 102 is substantially atmospheric pressure when receiving the subsequent substrate.

As described above, in some embodiments, the input chamber 102 and the process chamber 120 may be connected to each other via the first gate valve 116. In some embodiments, the first gate valve 116 may be a different type of valve, other than a gate valve. The first gate valve 116 may be opened, as shown in FIG. 2, to enable the substrate to be transferred from the input chamber 102 to the process chamber 120. The first gate valve 116 may be closed to environmentally isolate the input chamber 102 from the process chamber 120. For example, the first gate valve 116 may be closed when the CVD process is being performed on the substrate in the process chamber 120. In this way, the environmental conditions (e.g., the temperature and pressure) within the process chamber 120 will have no effect on the environmental conditions within the input chamber 102 when the first gate valve 116 is closed, allowing separate processes or operations requiring different environmental conditions to be conducted within each chamber at the same time. As such, while the CVD process is being performed on the substrate in the process chamber 120, a different (e.g., subsequent) substrate may be received within the input chamber 102 and prepared for subsequent conveyance into the process chamber 120. In some embodiments, the first gate valve 116 may be opened and closed automatically. For example, the first gate valve 116 may be configured to open and/or close based on when the CVD process within the process chamber 120 is set to start or when it is completed. In other examples, the first gate valve 116 may be configured to open and/or close based on the pressure within the input chamber 102. For example, the first gate valve 116 may be configured to open once the pressure in the input chamber 120 is substantially the same as the pressure within the process chamber 120. Once opened, the substrate may be conveyed from the input chamber 102 into the process chamber 120, and the first gate valve 116 may likewise be configured to automatically close once the substrate is in position within the process chamber 120, as an example. In yet another example, the first gate valve 116 may be configured to open once the CVD process being conducted within the process chamber 120 is complete and may further be configured to close once the CVD process is set to start. In still other embodiments, the first gate valve 116 may be opened and closed manually, such as by an operator or a user. In some embodiments, a surface of the first gate valve 116 may be mirror polished. In this way, the first gate valve 116 may be thermally isolated. Further, in this way, the first gate valve 116 may be configured to reflect visible light and/or infrared light back into the process chamber 120.

Similarly, as described above and in some embodiments, on a downstream end of the process chamber 120, the process chamber 120 and the output chamber 150 may be connected to each other via the second gate valve 146. In some embodiments, the second gate valve 146 may be a different type of valve, other than a gate valve. The second gate valve 146 may be opened, as shown in FIG. 2, to enable the substrate to be transferred from the process chamber 120 to the output chamber 150. The second gate valve 146 may be closed to environmentally isolate the output chamber 150 from the process chamber 120. For example, the second gate valve 146 may be closed when the CVD process is being performed on the substrate in the process chamber 120. In this way, the environmental conditions (e.g., the temperature and pressure) within the process chamber 120 will have no effect on the environmental conditions within output chamber 150 when the second gate valve 146 is closed, allowing separate processes or operations requiring different environmental conditions to be conducted within each chamber at the same time. As such, while the CVD process is being performed on the substrate in the process chamber 120, a different (e.g., previous) substrate may be discharged or removed from the output chamber 150 and the output chamber 150 may be prepared for receiving the substrate currently undergoing the CVD process in the process chamber 120. In some embodiments, the second gate valve 146 may be opened and closed automatically. For example, the second gate valve 146 may be configured to open and/or close based on when the CVD process within the process chamber 120 is set to start or when it is completed. In other examples, the second gate valve 146 may be configured to open and/or close based on the pressure within the output chamber 150. For example, the second gate valve 146 may be configured to open once the pressure in the output chamber 150 is substantially the same as the pressure within the process chamber 120. Once opened, the substrate may be conveyed from the process chamber 120 into the output chamber 150, and the second gate valve 146 may likewise be configured to automatically close once the substrate is in position within the output chamber 150, as an example. In yet another example, the second gate valve 146 may be configured to open once the CVD process being conducted within the process chamber 120 is complete and may further be configured to close once the CVD process is set to start. In still other embodiments, the second gate valve 146 may be opened and closed manually, such as by an operator or user. In some embodiments, the second gate valve 146 may be actively cooled. In some embodiments, a surface of the second gate valve 146 may be mirror polished. In this way, the second gate valve 146 may be thermally isolated. Further, in this way, the second gate valve 146 may be configured to reflect visible light and/or infrared light back into the process chamber 120.

As described above, the continuous-feed CVD system 100 includes the process chamber 120 downstream from the input chamber 102 that is configured to receive the substrate from the input chamber 102. The process chamber 120 may be configured to perform the CVD process on the substrate. As described above, the input chamber 102 may be configured to receive a subsequent substrate while the CVD process is being performed on the substrate. The process chamber 120 may be configured to be maintained at substantially vacuum pressure while the continuous-feed CVD system 100 is in use. The process chamber 120 may further include a heating enclosure 132. The heating enclosure 132 may be configured to be continuously operated while the continuous-feed CVD system 100 is in use. Said differently, an interior space of the heating enclosure 132 may be configured to be substantially maintained at the necessary reactive temperature while the continuous-feed CVD system 100 is in use. In other words, in some embodiments, the interior space of heating enclosure 132 may be configured to be maintained such that there are optimal processing conditions for the substrate throughout the CVD process.

Because certain pressures and temperatures are required to be attained and maintained within the process chamber 120 for the CVD process to take place, the process chamber 120 is configured to be environmentally isolated from the input chamber 102 and the output chamber 150 during certain points in the process according to embodiments of the invention. In this regard, the process chamber 120 may further include a first tubular connector 122 and a second tubular connector 134. The heating enclosure 132 may be connected to the first gate valve 116 via the first tubular connecter 122 and may be connected to the second gate valve 146 via the second tubular connecter 134.

The first tubular connector 122, as described above, may be disposed between the first gate valve 116 and the heating enclosure 132. By way of example, the first tubular connector 122 may comprise stainless steel, aluminum, titanium, nickel, molybdenum, tungsten, or quartz. The first tubular connector 122 may be configured to introduce at least one gas into the process chamber 120 such that the CVD process can be performed on the substrate. In some embodiments, the introduction of the at least one gas may be controlled, at least in part, via a gas control cabinet 164. As shown in FIG. 2, the first tubular connector 122 may further include first bellows 128. In some embodiments, the first bellows 128 may be flexible, such that the first bellows 128 may function as a spring and mechanically isolate components of the CVD system 100. In other words, in some embodiments, the first bellows 128 may dissipate and isolate vibrations of the heating enclosure 132, the first gate valve 116, the input chamber 102, and/or other components of the CVD system 100. As shown in FIG. 2, the first tubular connector 122 may further include a first O-ring 130. In particular, the first O-ring 130 may be configured such that an airtight seal is maintained between the first tubular connecter 122 and the heating enclosure 132. By way of example, the first O-ring 130 may comprise Kalrez® compounds, copper, Viton® compounds, or silicone. Said differently, the first O-ring 130 may be any material that can be used to maintain an airtight seal.

The second tubular connector 134, as described above, may be disposed between second gate valve 146 and the heating enclosure 132. By way of example, the second tubular connector 134 may comprise stainless steel, aluminum, titanium, nickel, molybdenum, tungsten, or quartz. The second tubular connector 134 may be configured to remove at least one gas from the process chamber 120. In some embodiments, a pump 138 may be connected to the second tubular connector 134 for controlling the pressure in the process chamber 120. In other embodiments, the pump 138 may be connected to another part of the process chamber 120. The pump 138 may be connected to the second tubular connector 134 via piping 136. In some embodiments, there may be one pump for the entire continuous-feed CVD system 100. In other words, in some embodiments, the same pump 138 may be used to control the pressure in the input chamber 102, the process chamber 120, and/or the output chamber 150. In some cases, for example, the pump 138 may be configured to control the pressure in the process chamber 120 such that the process chamber 120 is at substantially vacuum pressure while the continuous-feed CVD system 100 is in use. As shown in FIG. 2, the second tubular connector 134 may further include second bellows 142. In some embodiments, the second bellows 142 may be flexible, such that the second bellows 142 may function as a spring and mechanically isolate components of the CVD system 100. In other words, in some embodiments, the second bellows 142 may dissipate and isolate vibrations of the heating enclosure 132, the second gate valve 146, the output chamber 150, and/or other components of the CVD system 100. As shown in FIG. 2, the second tubular connector 134 may further include a second O-ring 140. In particular, the second O-ring 140 may be configured such that an airtight seal is maintained between the second tubular connector 134 and the heating enclosure 132. By way of example, the second O-ring 140 may comprise Kalrez® compounds, copper, Viton® compounds, or silicone. Said differently, the second O-ring 140 may be any material that can be used to maintain an airtight seal.

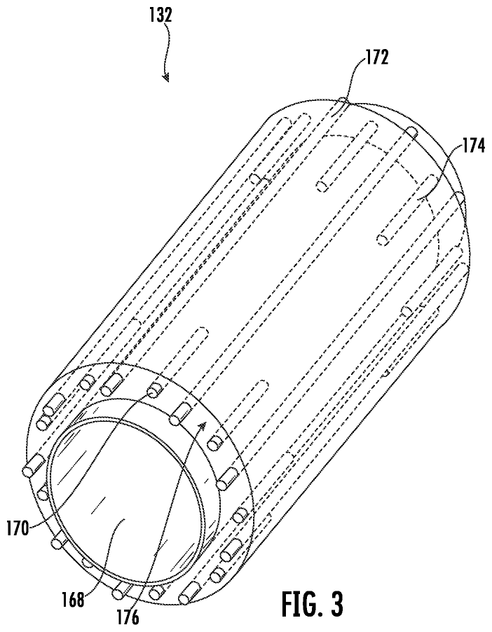

In FIG. 3 an example embodiment of the heating enclosure 132 is illustrated. As shown in FIG. 3 the heating enclosure 132 may be substantially cylindrical. In other embodiments, as shown in FIGS. 1 and 2, the heating enclosure 132 may be substantially rectangular. In some embodiments, for example, the heating enclosure 132 may include a cylindrical body 168 having a first end and a second end. The cylindrical body 168 may be configured to receive the substrate for the CVD process. The cylindrical body 168 may comprise any material capable of operating as part of the heating enclosure 132. For example, the cylindrical body 168 may comprise quartz, stainless steel, or aluminum in some embodiments.

As shown in FIG. 3, the cylindrical body 168 may be surrounded by a first plurality of heating elements 170 extending along an axial direction of the cylindrical body 168 from proximate the first end of the cylindrical body 168 towards the second end. In some embodiments, the length of the first plurality of heating elements 170 may be less than half the length of the cylindrical body 168. The cylindrical body 168 may be surrounded by a second plurality of heating elements 172 extending along an axial direction of the cylindrical body 168 from proximate the first end to proximate the second end. The cylindrical body 168 may also be surrounded by a third plurality of heating elements 174 extending along an axial direction of the cylindrical body 168 from proximate the second end of the cylindrical body 168 towards the first end. In some embodiments, the length of the third plurality of heating elements 174 may be less than half the length of the cylindrical body 168. By way of example, the second plurality of heating elements 172 may extend further towards the first end than the first plurality of heating elements 170 and the third plurality of heating elements 174.

With continued reference to FIG. 3, the first plurality of heating elements 170, the second plurality of heating elements 172, and/or the third plurality of heating elements 174 may be substantially cylindrical and may comprise silicon carbide. In some embodiments, the first plurality of heating elements 170, the second plurality of heating elements 172, and/or the third plurality of heating elements 174 may be flush against an outer surface of the cylindrical body 168. In other embodiments, as shown in FIG. 3, there may be a space between the first plurality of heating elements 170, the second plurality of heating elements 172, and/or the third plurality of heating elements 174 and the outer surface of the cylindrical body 168. By way of example, each first heating element 170 may be surrounded on either side by a second heating element 172. Similarly, by way of example, each third heating element 174 may be surrounded on either side by a second heating element 172.

The heating enclosure 132 may further include an insulator 176 surrounding the cylindrical body 168. In some embodiments, the insulator 176 may be ceramic. In some embodiments, such as in FIG. 3, the insulting layer 176 may be substantially the same shape as the cylindrical body 168. By way of example, as shown in FIG. 3, the first plurality of heating elements 170, the second plurality of heating elements 172, and/or the third plurality of heating elements 174 may be disposed within the insulator 176. Alternatively, the insulator 176 may surround the first plurality of heating elements 170, the second plurality of heating elements 172, and/or the third plurality of heating elements 174. In some embodiments, the insulator 176 may only cover a portion of the outer surface of the cylindrical body 168, while in other embodiments, the insulator 176 may cover the entire outer surface of the cylindrical body 168.

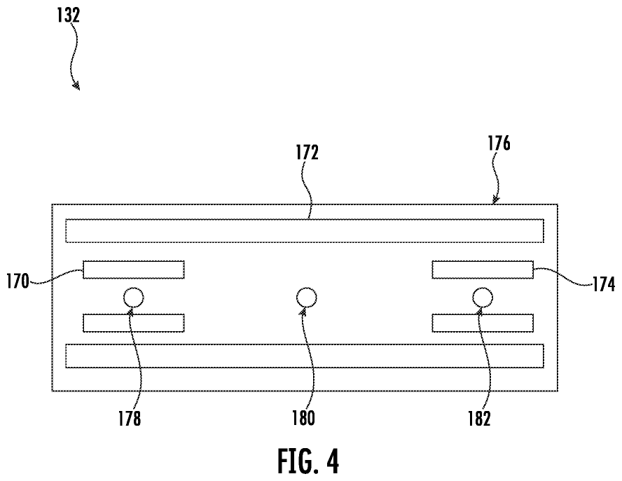

With reference to FIG. 4, a schematic illustration of an example heating enclosure 132 is depicted, illustrating the insulator 176, the first plurality of heating elements 170, the second plurality of heating elements 172, and the third plurality of heating elements 174. In some embodiments, as shown in FIG. 4, the heating enclosure 132 may further include a plurality of temperature sensors, such as temperature sensors 178, 180, and 182, configured to measure the temperature at various locations within the cylindrical body 168. The first plurality of heating elements 170, the second plurality of heating elements 172, and the third plurality of heating elements 174 may be controlled (e.g., turned on or off or raised or lowered to a certain temperature) based on measurements from the plurality of temperature sensors. In this way, the first plurality of heating elements 170, the second plurality of heating elements 172, and the third plurality of heating elements 174 may be controlled to ensure substantial uniformity and substantial stability of temperature throughout the heating enclosure 132. In some cases, the first plurality of heating elements 170 and the third plurality of heating elements 174 may be set at a higher temperature than the second plurality of heating elements 172 or may otherwise be configured to have different temperatures based on their relative lengths and positions so as to create a uniform and stable temperature environment throughout the heating enclosure 132.

As described above, in some embodiments, the continuous-feed CVD system 100 includes the output chamber 150 configured to allow for discharge, or removal, of a previous substrate while the CVD process is being performed on the substrate in the process chamber 120. As described above, in some embodiments, the output chamber 150 may be further configured to receive the substrate from the process chamber 120 and allow the substrate to be discharged or removed from the continuous-feed CVD system 100, such as by an operator or a user. As shown in FIGS. 1 and 2, the output chamber 150 may be substantially cylindrical in some embodiments. In other embodiments the output chamber 150 may be substantially rectangular. The output chamber 150 may comprise any material capable of allowing a substantially vacuum pressure to be maintained inside the output chamber 150. By way of example, the output chamber 150 may comprise stainless steel, aluminum, or quartz. The output chamber 150 may further include viewing windows 152 such that the interior of the output chamber 150 can be viewed from outside the chamber by an operator or a user. The output chamber 150 may further include piping 154. The piping 154 may be configured to circulate a coolant in some embodiments. As such, piping 154 may be configured to actively cool the output chamber 150.

As shown in FIG. 1, the substrate may be discharged, or removed, via a second door 156 connected by a hinge or other mechanism to a first end of the output chamber 150. In some embodiments, the second door 156 may be manually opened. Alternatively, the second door 156 may be automatically opened when the continuous-feed CVD system 100 is ready to allow the discharge, or removal, of a substrate. In other embodiments, the output chamber 150 may be configured to allow the discharge, or removal, of a substrate via an opening on the side of the output chamber 150.

In some embodiments, the output chamber 150 may comprise a second mechanism configured to transfer the substrate from the process chamber 120 to the output chamber 150. In some embodiments, the output chamber 150 may be configured such that the second mechanism may be stored in a second mechanism housing 158. The second mechanism may be configured to transfer the substrate from the process chamber 120 to the output chamber 150 when the output chamber 150 is at substantially vacuum pressure. In this way, in some embodiments, the second mechanism may be configured such that the substrate may be transferred from the process chamber 120 to the output chamber 150, either automatically or in response to actuation by a remote operator or a remote user.

In some embodiments, a pump 160 may be connected to the output chamber 150 for controlling the pressure in the output chamber 150. The pump 160 may be connected to the output chamber 150 via piping 162. In some embodiments, there may be one pump for the entire continuous-feed CVD system 100. In other words, in some embodiments, the same pump 160 may be used to control the pressure in the input chamber 102, the process chamber 120, and/or the output chamber 150.

In some cases, for example, the pump 160 may be configured to control the pressure in the output chamber 150 such that the output chamber 150 is at substantially atmospheric pressure when discharging, or allowing for the removal of, the previous substrate and may further be configured to control the pressure in the output chamber 150 such that the output chamber 150 is at substantially vacuum pressure when the substrate is being transferred from the process chamber 120 to the output chamber 150. The pump 160 may also be configured to control the pressure in the output chamber 150 such that the pressure in the output chamber 150 is substantially atmospheric pressure when discharging, or allowing for the removal of, the substrate.

In some embodiments, the continuous-feed CVD system 100 may not include the output chamber 150. In such embodiments, the input chamber 102 may be configured to receive the substrate into the continuous-feed CVD system 100 and may also be configured to discharge, or allow for the removal of, the substrate from the continuous-feed CVD system 100. In other words, in some embodiments, the input chamber 102 may receive the substrate into the continuous-feed CVD system 100. In some embodiments, after receiving the substrate, the input chamber may be configured to reduce the pressure in the input chamber 102 to substantially vacuum pressure in preparation for entry of the substrate into the process chamber 120. In some embodiments, once the pressure in the input chamber 102 is reduced to substantially vacuum pressure, the first gate valve 116 may be opened, to enable the substrate to be transferred from the input chamber 102 to the process chamber 120. In some embodiments, the first gate valve 116 may be closed to environmentally isolate the input chamber 102 from the process chamber 120, such as when the process chamber 120 is in the operational state and the CVD process is being performed on the substrate in the process chamber 120. Once the CVD process is completed, in some embodiments, the first gate valve 116 may be opened and the substrate may be transferred back into the input chamber 102. In some embodiments, the first gate valve 116 may then be closed to environmentally isolate the input chamber 102 and the process chamber 120. Then, in some embodiments, the pressure in the input chamber 102 may be increased to substantially atmospheric pressure and the input chamber 102 may discharge, or allow for the removal of, the substrate from the system.

With continued reference to FIGS. 1 and 2, the continuous-feed CVD system 100 may include a control cabinet 166. The control cabinet 166 may include a processor, a memory, and communications circuitry. The control cabinet 166 may further include a display 190. The control cabinet 166 may further include input means 192. By way of example, the input means 192 may be a keyboard. The control cabinet may be configured to allow a user or an operator to control the operations of the continuous-feed CVD system 100. For example, the operator or the user may access the control cabinet to control the pressure in the input chamber 102, the process chamber 120, and/or the output chamber 150. As another example, the operator or the user may access the control cabinet to initiate the transfer of the substrate from the input chamber 102 to the process chamber 120 and from the process chamber 120 to the output chamber 150. In yet another example, the operator or the user may access the control cabinet to control the temperature in the heating enclosure 132. In yet another example, the operator or the user may access the control cabinet to open and close the first gate valve 116 and the second gate valve 146 and/or to open and close the first door 106 and the second door 156.

### Example Method

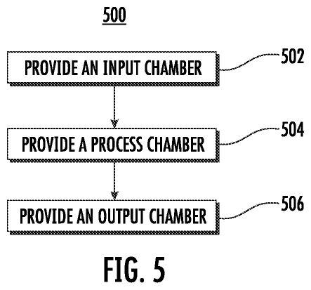

With reference to FIG. 5, an example method of providing a continuous-feed CVD process is illustrated. The method (e.g., method 500) may include the step of providing an input chamber at operation 502. As described above, the input chamber may be configured to receive a substrate via a first door connected to a first end of the input chamber. The first door may further comprise a first mechanism housing. The first mechanism housing may include a first mechanism configured for transferring the substrate from the input chamber to the process chamber. As described above, the input chamber may be configured to receive the substrate at substantially atmospheric pressure. The input chamber may further be configured to transfer the substrate to the process chamber at substantially vacuum pressure. As described above, the input chamber may be configured to receive a subsequent substrate while the CVD process is being performed in the process chamber.

The method (e.g., method 500) may include the step of providing a process chamber at operation 504. The process chamber may be configured to perform the CVD process on the substrate. The process chamber may be configured to be maintained at substantially vacuum pressure and substantially at the necessary reactive temperature while the continuous-feed CVD system is in use. As described above, the process chamber may be downstream from the input chamber and connected to the input chamber via the first gate valve. In this regard, the first gate valve may be opened to enable the substrate to be transferred from the input chamber to the process chamber. The first gate valve may be closed to environmentally isolate the process chamber from the input chamber. As described above, on a downstream end of the process chamber, the process chamber may be connected to an output chamber via a second gate valve. In this regard, the second gate valve may be opened to enable the substrate to be transferred from the process chamber to the output chamber. The first gate valve may be closed to environmentally isolate the process chamber from the output chamber.

The method (e.g., method 500) may include the step of providing an output chamber at operation 506. As described above, the output chamber may be downstream from the process chamber and may be connected to the process chamber via the second gate valve. As described above, the output chamber may be configured to allow for discharge or removal of a previous substrate while the CVD process is being performed on the substrate in the process chamber. In other words, the output chamber may be configured to receive the substrate from the process chamber and may be configured to allow for the discharge or removal, such as by an operator, of the substrate via a second door connected to a second end of the output chamber. The second door may further comprise a second mechanism housing. The second mechanism housing may include a second mechanism configured for transferring the substrate from the process chamber to the output chamber. As described above, the output chamber may be configured to receive the substrate from the process chamber at substantially vacuum pressure and may be configured to discharge, or allow for the removal of, the substrate at substantially atmospheric pressure.

Many modifications and other embodiments of the inventions set forth herein will come to mind to one skilled in the art to which these inventions pertain having the benefit of the teachings presented in the foregoing descriptions and the associated drawings. Although the figures only show certain components of the methods and systems described herein, it is understood that various other components may also be part of the continuous-feed CVD system. In addition, the method described above may include fewer steps in some cases, while in other cases may include additional steps. Modifications to the steps of the method described above, in some cases, may be performed in any order and in any combination.

Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A chemical vapor deposition system comprising:
a first chamber configured to receive a substrate;
a second chamber downstream from the first chamber, wherein the second chamber is configured to receive the substrate from the first chamber, and wherein, in an operational state, a chemical vapor deposition process is performed on the substrate within the second chamber; and
a third chamber downstream from the second chamber, wherein the third chamber is configured to receive the substrate from the second chamber upon completion of the chemical vapor deposition process within the second chamber,
wherein the second chamber is configured to be environmentally isolated from the first chamber and the third chamber when in the operational state, and
wherein, in the operational state, the first chamber is configured to receive a subsequent substrate in preparation for a subsequent chemical vapor deposition process to be performed on the subsequent substrate.

2. The chemical vapor deposition system of claim 1, wherein, in the operational state, the third chamber is configured to allow a user to withdraw a previous substrate, wherein the previous substrate has previously undergone the chemical vapor deposition process within the second chamber.

3. The chemical vapor deposition system of claim 2, wherein the first chamber is configured to be at a first pressure when receiving the subsequent substrate and wherein the third chamber is configured to be at the first pressure when allowing the user to withdraw the previous substrate.

4. The chemical vapor deposition system of claim 1, wherein the second chamber is at a second pressure.

5. The chemical vapor deposition system of claim 1, further comprising a first mechanism configured to be actuated to transfer the substrate from the first chamber to the second chamber and a second mechanism configured to be actuated to transfer the substrate from the second chamber to the third chamber.

6. The chemical vapor deposition system of claim 1, wherein the substrate comprises a plurality of substrates.

7. The chemical vapor deposition system of claim 1, wherein the third chamber is actively cooled.

8. A chemical vapor deposition method comprising:
providing a first chamber configured to receive a substrate;
providing a second chamber downstream from the first chamber, wherein the second chamber is configured to receive the substrate from the first chamber, and wherein, in an operational state, a chemical vapor deposition process is performed on the substrate within the second chamber; and
providing a third chamber downstream from the second chamber, wherein the third chamber is configured to receive the substrate from the second chamber upon completion of the chemical vapor deposition process within the second chamber,
wherein the second chamber is configured to be environmentally isolated from the first chamber and the third chamber when in the operational state, and
wherein, in the operational state, the first chamber is configured to receive a subsequent substrate in preparation for a subsequent chemical vapor deposition process to be performed on the subsequent substrate.

9. The chemical vapor deposition method of claim 8, wherein, in the operational state, the third chamber is configured to allow a user to withdraw a previous substrate, wherein the previous substrate has previously undergone the chemical vapor deposition process within the second chamber.

10. The chemical vapor deposition method of claim 9, wherein the first chamber is configured to be at a first pressure when receiving the subsequent substrate and wherein the third chamber is configured to be at the first pressure when allowing the user to withdraw the previous substrate.

11. The chemical vapor deposition method of claim 8, wherein the second chamber is at a second pressure.

12. The chemical vapor deposition method of claim 8, further comprising providing a first mechanism configured to be actuated to transfer the substrate from the first chamber to the second chamber and providing a second mechanism configured to be actuated to transfer the substrate from the second chamber to the third chamber.

13. The chemical vapor deposition method of claim 8, wherein the substrate comprises a plurality of substrates.

14. The chemical vapor deposition method of claim 8, wherein the third chamber is actively cooled.

15. A chamber for conducting chemical vapor deposition, the chamber comprising:
a heating enclosure configured to maintain a substrate at a predefined temperature for conducting a chemical vapor deposition process within the chamber, wherein the heating enclosure comprises a cylindrical body having a first end and a second end;
a first valve proximate the first end of the cylindrical body, wherein the substrate is received within the cylindrical body via the first valve and wherein the first valve is configured to environmentally isolate the chamber when in an operational state during which the chemical vapor deposition process is performed on the substrate;
a second valve proximate the second end of the cylindrical body, wherein the substrate is discharged from the chamber via the second valve and wherein the second valve is configured to environmentally isolate the chamber when in the operational state; and
a first tubular connector and a second tubular connector, the first tubular connector engaged with the first valve and the first opening of the cylindrical body and extending between the first valve and the first opening, the second tubular connector engaged with the second opening of the cylindrical body and the second valve and extending between the second opening and the second valve,
wherein the first tubular connector and the second tubular connector mechanically isolate the cylindrical body from the first valve and the second valve.

16. The chamber of claim 15, wherein the first tubular connector comprises first flexible bellows and wherein the second tubular connector comprises second flexible bellows.

17. The chamber of claim 15, wherein the first valve comprises a first gate valve and wherein the second valve comprises a second gate valve.

18. The chamber of claim 15, wherein a surface of the first valve is mirror polished and wherein a surface of the second valve is mirror polished.

19. The chamber of claim 15, wherein the second valve is actively cooled.

20. A heating enclosure for conducting chemical vapor deposition, the heating enclosure comprising:
a cylindrical body having a first end and a second end, wherein the cylindrical body is configured to receive a substrate;
a first plurality of heating elements disposed around an outer surface of the cylindrical body and extending along an axial direction of the cylindrical body from the first end of the cylindrical body toward the second end of the cylindrical body, wherein a first length of the each of the first plurality of heating elements is less than half a length of the cylindrical body;
a second plurality of heating elements disposed around the outer surface of the cylindrical body and extending along an axial direction of the cylindrical body from the first end of the cylindrical body to the second end of the cylindrical body; and
a third plurality of heating elements disposed around the outer surface of the cylindrical body and extending along an axial direction of the cylindrical body from the second end of the cylindrical body toward the first end of the cylindrical body, wherein a second length of each of the third plurality of heating elements is less than half the length of the cylindrical body,
wherein the first plurality of heating elements, the second plurality of heating elements, and the third plurality of heating elements are configured to maintain a first temperature within the cylindrical body.

21. The heating enclosure of claim 20, further comprising:
a controller
a plurality of temperature sensors configured to measure temperatures in the cylindrical body, wherein the plurality of temperature sensors are in communication with the controller, and wherein the controller is further configured to control at least one of the first, second, and third plurality of heating elements at least partly in response to measurements of the plurality of temperature sensors.

22. The heating enclosure of claim 20, wherein the first plurality of heating elements and the third plurality of heating elements are set at a second temperature and the second plurality of heating elements are set at a third temperature.

23. The heating enclosure of claim 22, wherein the second temperature is greater than the third temperature.

24. The heating enclosure of claim 20, wherein the cylindrical body comprises quartz.

25. The heating enclosure of claim 20, wherein the first plurality of heating elements, the second plurality of heating elements, and the third plurality of heating elements comprise silicon carbide.

26. The heating enclosure of claim 20, further comprising an insulator around the outer surface of the cylindrical body.

27. The heating enclosure of claim 26, wherein the insulator comprises ceramic.

28. A chemical vapor deposition system comprising:
a first chamber configured to receive a substrate; and
a second chamber downstream from the first chamber, wherein the second chamber is configured to receive the substrate from the first chamber, and wherein, in an operational state, a chemical vapor deposition process is performed on the substrate within the second chamber;
wherein the second chamber is configured to be environmentally isolated from the first chamber when in the operational state, and
wherein the first chamber is configured to receive the substrate from the second chamber upon completion of the chemical vapor deposition process within the second chamber.
